(19) United States
(12) Patent Application Publication
(10) Pub. No.: US 2025/0212553 A1
(43) Pub. Date: Jun. 26, 2025

(54) MICROELECTRONIC COMPONENT TRANSFER APPARATUS

(71) Applicant: PlayNitride Display Co., Ltd., MiaoLi County (TW)

(72) Inventors: Yi-Ching Chen, MiaoLi County (TW); Hsiang-Wen Tang, MiaoLi County (TW); Tai-Jyun Jhang, MiaoLi County (TW); Zong Huei Tsai, MiaoLi County (TW)

(73) Assignee: PlayNitride Display Co., Ltd., MiaoLi County (TW)

(21) Appl. No.: 18/395,748

(22) Filed: Dec. 26, 2023

(51) Int. Cl. H01L 33/00; H01L 25/075

(52) U.S. Cl. CPC H10H 20/01; H01L 25/0753; H10H 20/0364

(57) ABSTRACT

A microelectronic component transfer apparatus including a backplane carrier, a substrate carrier, a degluing laser source and a soldering laser source is provided. The backplane carrier is adapted to carry a backplane. The substrate carrier is adapted to carry a substrate. The substrate carrier and the backplane carrier are arranged opposite to each other. The degluing laser source is arranged on a side of the backplane carrier away from the substrate carrier. The degluing laser source is adapted to emit a degluing laser toward a direction of the substrate carrier. The soldering laser source is disposed on a side of the substrate carrier away from the backplane carrier. The soldering laser source is adapted to emit a soldering laser toward a direction of the backplane carrier. The microelectronic component transfer equipment is suitable for transferring a microelectronic component disposed on the substrate to the backplane.

### BACKGROUND

### Technical Field

This disclosure relates to a transfer apparatus, and in particular to a microelectronic component transfer apparatus.

### Description of Related Art

In recent years, with the high manufacturing cost of organic light-emitting diode (OLED) display panels and their lifespan unable to compete with the current mainstream displays, micro LED displays have gradually attracted the investment attention of major technology companies. In addition to the advantages of low energy consumption and long material lifespan, micro LED displays also have excellent optical performance, such as high color saturation, fast response speed, and high contrast.

On the other hand, in order to achieve lower production costs and greater product design flexibility, the manufacturing process of micro LED displays often adopts the method of chip transfer (e.g., mass transfer technology). How to improve the quality and/or yield of chip transfer is indeed a research topic.

### SUMMARY

This disclosure provides a microelectronic component transfer apparatus, which has better process quality and/or yield in application.

The microelectronic component transfer apparatus of this disclosure includes a backplane carrier, a substrate carrier, a degluing laser source, and a soldering laser source. The backplane carrier is used to carry the backplane. The substrate carrier is used to carry the substrate. The substrate carrier and the backplane carrier are configured opposite to each other. The degluing laser source is configured on the side of the backplane carrier far away from the substrate carrier. The degluing laser source is suitable for emitting a degluing laser in the direction of the substrate carrier. The soldering laser source is configured on the side of the substrate carrier far away from the backplane carrier. The soldering laser source is suitable for emitting a soldering laser in the direction of the backplane carrier. The microelectronic component transfer apparatus is suitable for transferring the microelectronic components disposed on the substrate to the backplane.

Based on the above, when the microelectronic component transfer process is carried out by the microelectronic component transfer apparatus of this disclosure, due to the corresponding configuration of the degluing laser source and the soldering laser source, the transfer process may have better process quality and/or yield.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a partial three-dimensional schematic diagram of a microelectronic component transfer apparatus according to an embodiment of this disclosure.

FIG. 2A is a partial side view schematic diagram of a microelectronic component transfer apparatus and corresponding transfer object according to an embodiment of this disclosure.

FIG. 2B is a partial top view schematic diagram of a microelectronic component transfer apparatus and corresponding transfer object according to an embodiment of this disclosure.

FIG. 3A is a partial side view schematic diagram of a microelectronic component transfer apparatus and corresponding transfer object according to an embodiment of this disclosure.

FIG. 3B is a partial top view schematic diagram of a microelectronic component transfer apparatus and corresponding transfer object according to an embodiment of this disclosure.

FIGS. 4A and 4B are partial side view schematic diagrams of a microelectronic component transfer apparatus and corresponding transfer object according to an embodiment of this disclosure.

FIG. 5A is a partial side view schematic diagram of a microelectronic component transfer apparatus and corresponding transferred object according to an embodiment of this disclosure.

FIG. 5B is a partial top view schematic diagram of a microelectronic component transfer apparatus and corresponding transferred object according to an embodiment of this disclosure.

FIG. 6A is a partial side view schematic diagram of a microelectronic component transfer apparatus and corresponding transferred object according to an embodiment of this disclosure.

FIG. 6B is a partial top view schematic diagram of a microelectronic component transfer apparatus and corresponding transferred object according to an embodiment of this disclosure.

FIGS. 7A to 7C are partial side view schematic diagrams of a microelectronic component transfer process performed by a microelectronic component transfer apparatus according to an embodiment of the disclosure.

FIGS. 8A to 8C are partial side view schematic diagrams of a microelectronic component transfer process performed by a microelectronic component transfer apparatus according to an embodiment of the disclosure.

FIGS. 9A to 9B are partial side view schematic diagrams of a microelectronic component transfer process performed by a microelectronic component transfer apparatus according to an embodiment of the disclosure.

FIGS. 10A to 10B are partial side view schematic diagrams of a microelectronic component transfer process performed by a microelectronic component transfer apparatus according to an embodiment of the disclosure.

### DESCRIPTION OF THE EMBODIMENTS

The following description may be referred to the drawing of this implementation example to more comprehensively explain the disclosure. However, this disclosure may also be embodied in various different forms and should not be limited to the implementation examples described in the description. The sizes of some components, layers, or regions in the drawing may be enlarged for clarity. The same or similar reference numbers may indicate the same or similar components, and the following paragraphs will not elaborate on them one by one. In addition, the directional terms mentioned in the implementation examples, such as: up, down, top, or bottom, etc., are only for reference to the direction of the drawings. Therefore, unless specifically stated, the directional terms used are for explanation and not for limiting this disclosure. Moreover, to clearly indicate the directional relationship between different drawings, in some drawings, the corresponding directions are exemplarily represented by a Cartesian coordinate system (e.g., XYZ rectangular coordinate system), but this disclosure is not limited thereto.

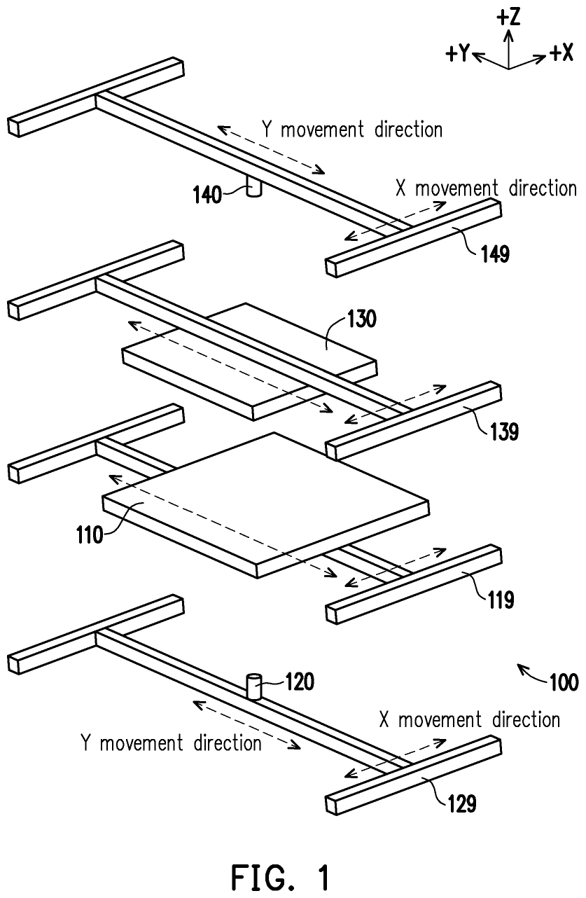

FIG. 1 is a partial three-dimensional schematic diagram of a microelectronic component transfer apparatus according to an embodiment of this disclosure.

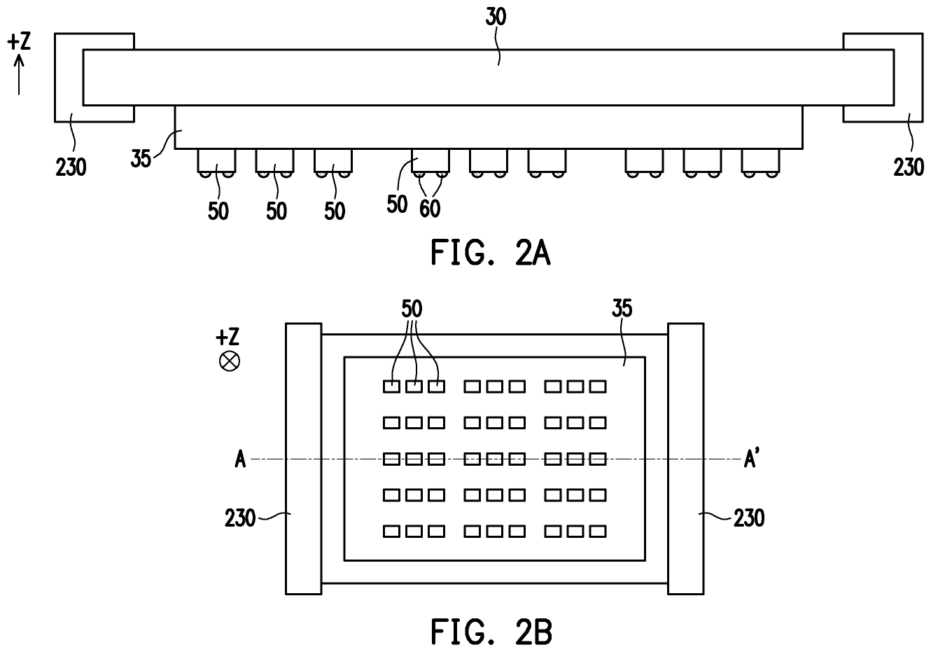

Referring to FIG. 1, the microelectronic component transfer apparatus 100 includes a backplane carrier 110, a substrate carrier 130, a degluing laser source 120, and a soldering laser source 140. The backplane carrier 110 is used to carry the backplane 10 (as shown in a subsequent drawing). The substrate carrier 130 is configured relative to or corresponding to the backplane carrier 110. The substrate carrier 130 is used to carry the substrate 30 (as shown in a subsequent drawing). The degluing laser source 120 is configured on a side of the backplane carrier 110 far from the substrate carrier 130. The degluing laser source 120 may emit a degluing laser 121 towards the substrate carrier 130. The soldering laser source 140 is configured on a side of the substrate carrier 130 far from the backplane carrier 110. The soldering laser source 140 may emit a soldering laser 141 towards the backplane carrier 110. Moreover, by using the microelectronic component transfer apparatus 100, at least one microelectronic component 50 originally disposed on the substrate 30 (as shown in FIGS. 2A to 4B or FIGS. 7A to 10B) may be transferred to the backplane 10. A process of transferring the microelectronic component 50 originally disposed on the substrate 30 to the backplane 10 by the microelectronic component transfer apparatus 100 will be described in detail later.

The backplane carrier 110 may be configured on a corresponding two-dimensional translation equipment 119, and the two-dimensional translation equipment 119 may include or connect to a corresponding movable part (e.g., a motor, a roller, a ball, a gear, a gear track, a toothed belt, a belt, etc., but not limited). The substrate carrier 130 may be configured on a corresponding two-dimensional translation equipment 139, and the two-dimensional translation equipment 139 may include or connect to a corresponding movable part. The degluing laser source 120 may be configured on a corresponding platform 129, and the platform 129 may include or connect to a corresponding movable part. The soldering laser source 140 may be configured on a corresponding platform 149, and the platform 149 may include or connect to a corresponding movable part. The backplane carrier 110, the substrate carrier 130, the platform 129 and/or the platform 149 may be signally connected to a control unit (not shown). The control unit may include corresponding hardware and/or software. In this way, the backplane carrier 110, the substrate carrier 130, the degluing laser source 120 and/or the soldering laser source 140 may be moved in a corresponding direction (e.g., along the X direction, the Y direction, the Z direction, a direction parallel to the XY plane, a direction parallel to the YZ plane and/or a direction parallel to the XZ plane) and/or rotated (e.g., clockwise or counterclockwise rotation along a certain axis) by the control unit. For example, the backplane carrier 110 and the substrate carrier 130 may be driven by corresponding two-dimensional translation equipment parallel to each other to change the relative positions of the backplane carrier 110 and the substrate carrier 130 with the degluing laser source 120 and the soldering laser source 140. For example, the degluing laser source 120 and the soldering laser source 140 may be driven by corresponding two-dimensional translation equipment respectively, and may be moved on a plane (which may be a virtual plane) parallel to the substrate 30 and the backplane 10. In addition, the degluing laser source 120 and/or the soldering laser source 140 may also be signally connected to the control unit. The degluing laser source 120 and/or the soldering laser source 140 may be controlled by the control unit to perform corresponding actions (including but not limited to: emitting a corresponding light beam).

In an embodiment, the degluing laser source 120 is suitable for emitting laser in the ultraviolet (UV) light region. Ultraviolet light is more suitable for decomposing corresponding polymer. Laser in the ultraviolet light region, for example, is an excimer (e.g., KrF) laser with a wavelength of about 248 nanometers (nm), a semiconductor-pumped solid-state laser with a wavelength of about 266 nanometers, or a semiconductor-pumped solid-state laser with a wavelength of about 355 nanometers. In an embodiment, a pulse repetition rate of the degluing laser source 120 is about 1 MHz, and a pulse width of the degluing laser source 120 is about 1 microsecond (μs). In an embodiment, a pulse repetition rate of the degluing laser source 120 is about 1 GHz, and a pulse width of the degluing laser source 120 is about 1 nanosecond (ns). In an embodiment, a transmittance of the laser (e.g., the subsequent degluing laser 121) emitted by the degluing laser source 120 to the backplane carrier 110 may be higher than or approximately equal to 60%; or, even higher than or approximately equal to 80%; or, even higher than or approximately equal to 90%.

In an embodiment, the soldering laser source 140 is suitable for emitting laser in the infrared (IR) light region. Infrared light is more suitable for being absorbed by metal material, thereby generating corresponding thermal energy. Laser in the infrared light region, for example, is an Nd:YAG laser with a wavelength of about 1064 nanometers, an Er:YAG laser with a wavelength of about 2936 nanometers, or an AlGaAs laser with a wavelength of about 905 nanometers. In an embodiment, in order to reduce excessive heat accumulation, a pulse width of the soldering laser source 140 is shorter, for example, about a level of picoseconds (ps) or femtoseconds (fs). In an embodiment, an output power of single pulse of the soldering laser source 140 is about 1 mJ/cm² to 100 mJ/cm². In an embodiment, a transmittance of the laser (e.g., the subsequent soldering laser 141) emitted by the soldering laser source 140 to the substrate carrier 130 may be higher than or approximately equal to 60%; or, even higher than or approximately equal to 80%; or, even higher than or approximately equal to 90%.

FIG. 2A is a partial side view schematic diagram of a microelectronic component transfer apparatus and corresponding transfer object according to an embodiment of the disclosure. FIG. 2B is a partial overhead view schematic diagram of a microelectronic component transfer apparatus and corresponding transfer object according to an embodiment of the disclosure. For example, FIG. 2A may be a side view schematic diagram corresponding to the A-A′ section line as shown in FIG. 2B.

Referring to FIGS. 2A and 2B, the substrate carrier 230 (a type of the substrate carrier 130) may include a corresponding snap, a corresponding buckle, and/or a corresponding clamp, suitable for carrying the corresponding substrate 30. The substrate 30, for example, may include a glass substrate, a polymer substrate, or a polymer film (e.g., ultraviolet tape (UV tape) or blue tape), but the disclosure is not limited thereto.

One side of the substrate 30 facing the backplane 10 has an adhesive layer 35. The adhesive layer 35 may temporarily fix the microelectronic component 50 on (below in the drawing) the substrate 30. The adhesive layer 35 may be reduced adhesion or be decomposed by being heat and/or being emitting by a corresponding light (e.g., the degluing laser 121), therefore allowing the microelectronic component 50 with reduced adhesion to be separated from the substrate 30. A material of the adhesive layer 35 is a polymer that is more suitable for being decomposed by ultraviolet light, for example, it may include light to heat conversion (LTHC) release material, thermally denatured release material, thermally fusible release material, or cold brittle release material, but the disclosure is not limited thereto. In an embodiment, the material of the adhesive layer 35 may include corresponding organic material (e.g., benzocyclobutene, phenol formaldehyde resin, epoxy resin, polyisoprene rubber or a combination thereabove) or inorganic material (e.g., silicon oxide, silicon nitride, silicon oxynitride or a combination thereabove).

The microelectronic component 50 may include a light-emitting chip (e.g., micro light-emitting diodes (uLED); but not limited) or an integrated circuit (IC), but the disclosure is not limited thereto. In addition, for simplicity or clarity, not all microelectronic components 50 are labelled individually in the drawing.

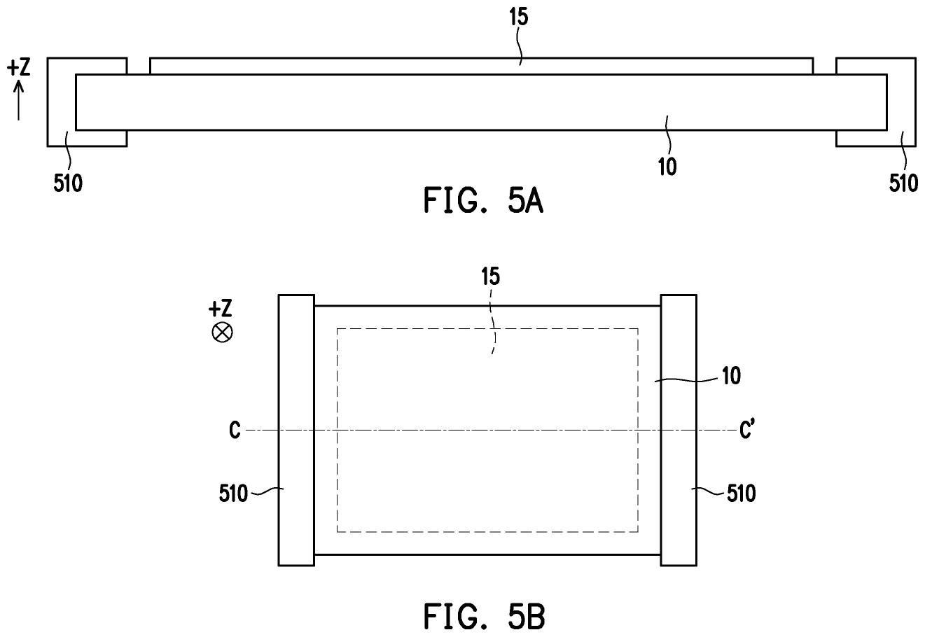

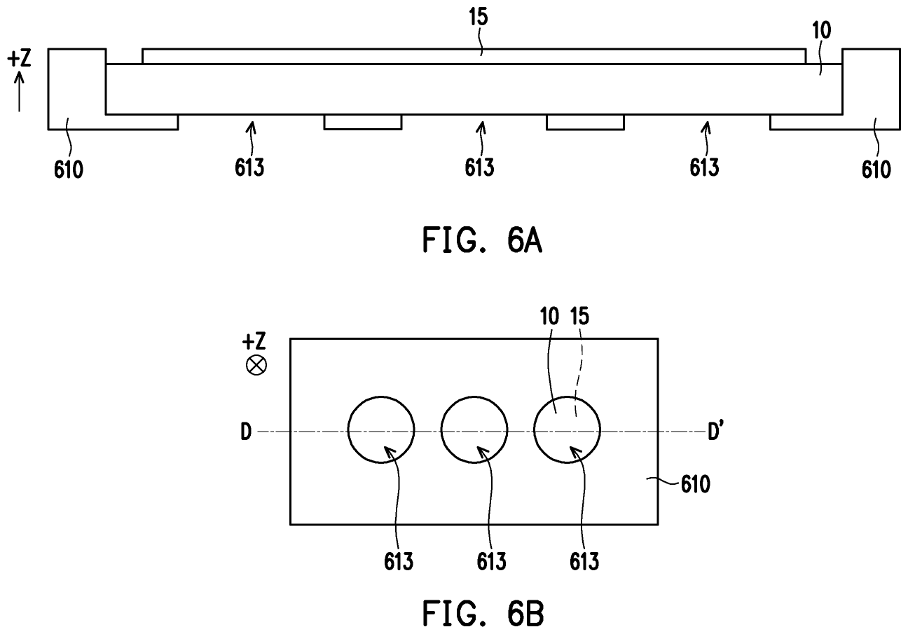

In an embodiment, a side of the microelectronic component 50 facing the backplane 10 may have a conductive connector 60 (e.g., a solder ball, but not limited), to facilitate a subsequent step to connect the microelectronic component 50 to an appropriate position of the backplane 10 (e.g., a corresponding metal wiring 15 of the backplane 10 as shown in in FIG. 5A or FIG. 6A) in an appropriate manner (e.g., soldering, but not limited). In an unillustrated embodiment, a conductive connector (which may be the same or similar to the conductive connector 60) may be disposed on a side of the backplane 10 facing the microelectronic component 50. In addition, for simplicity or clarity, not all conductive connectors 60 are labelled individually in the drawing, and the conductive connector 60 is omitted in some drawings (e.g., subsequent drawings). In some embodiments, the conductive connector 60 is an electrode of the microelectronic component 50, used to provide an electrical connection between the microelectronic component 50 and the metal wiring 15.

It is worth noting that the disclosure does not limit the plurality of microelectronic components 50 temporarily fixed on the substrate 30 to be the same or different. For example, all of the microelectronic components 50 may be light-emitting chips. For example, the light-emitting chip may be a red light-emitting chip, a green light-emitting chip, or a blue light-emitting chip.

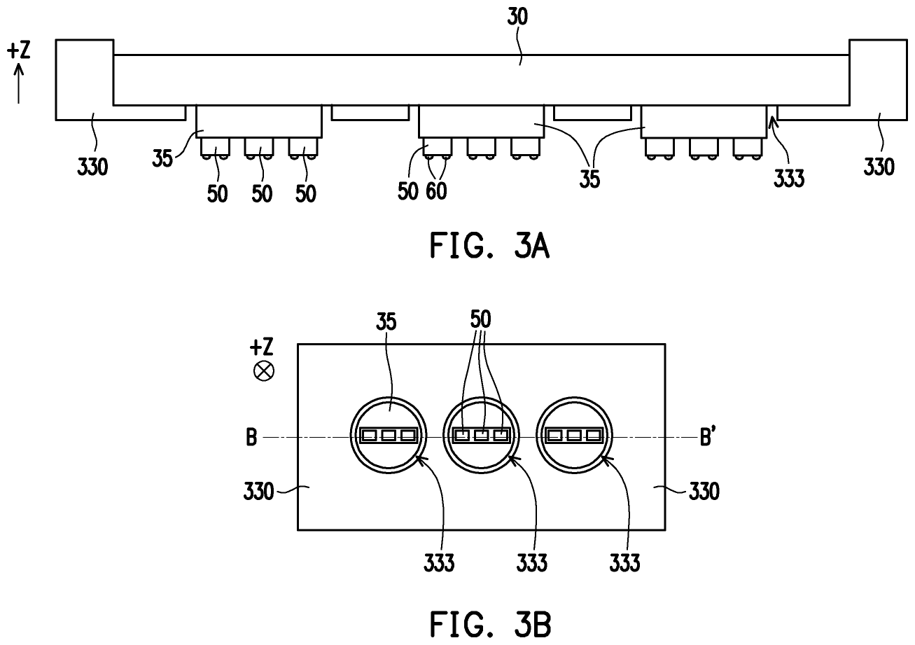

FIG. 3A is a partial side view schematic of a microelectronic component transfer apparatus and corresponding transfer object according to an embodiment of the disclosure. FIG. 3B is a partial overhead view schematic of a microelectronic component transfer apparatus and corresponding transfer object according to an embodiment of the disclosure. For example, FIG. 3A may be a side view schematic corresponding to the B-B′ section line as shown in FIG. 3B.

Referring to FIGS. 3A and 3B, the substrate carrier 330 (a type of the substrate carrier 130) may include a corresponding snap, a corresponding buckle, and/or a corresponding clamp, suitable for carrying the corresponding substrate 30. In an embodiment, the substrate carrier 330 has a corresponding hollow structure 333. The hollow structure 333 may correspond to an irradiation area of the laser emitted by the laser source (e.g., the soldering laser 141 emitted by the soldering laser source 140), suitable for performing a corresponding microelectronic component transfer step. The number, size, and/or shape of the hollow structure 333 may be adjusted according to a design request, and are not limited in the disclosure. In some embodiments, the hollow structure 333 may reduce the weight of the substrate carrier 330.

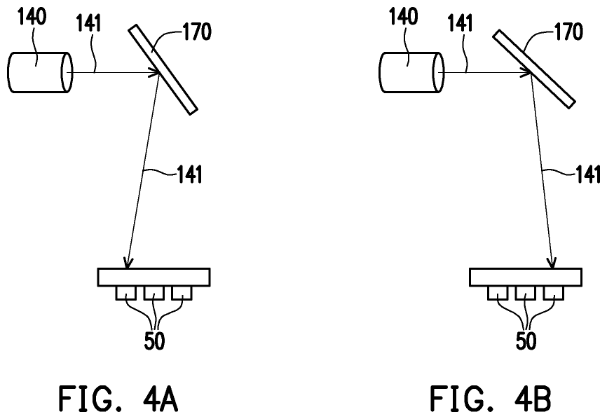

FIGS. 4A and 4B are partial side view schematics of a microelectronic component transfer apparatus and corresponding transfer object according to an embodiment of the disclosure.

In an embodiment, a laser source (e.g., the degluing laser source 120 and/or the soldering laser source 140) may change or adjust the optical path and/or corresponding emission direction of the laser (e.g., the degluing laser 121 and/or the soldering laser 141) through an appropriate optical guide device 170. The optical guide device 170 may include a galvo, a prism, a reflector, an optical fiber, an optical tube, or a combination thereabove, but the disclosure is not limited thereto.

It is worth noting that an optical path of the laser and/or the corresponding emission direction may be adjusted or integrated by the methods described in one or more of the aforementioned embodiments. For example, the corresponding laser source (e.g., the degluing laser source 120 and/or soldering laser source 140) may first be roughly moved or rotated to an appropriate position (which may be referred to as rough alignment) by a movable part of the carrier (e.g., the backplane carrier 110 and/or the substrate carrier 130); then, the laser (e.g., the degluing laser 121 and/or the soldering laser 141) is irradiated to a more precise position (which may be referred to as fine alignment) by an appropriate optical guide device 170.

As an examplify shown in FIGS. 4A and 4B, due to a smaller size of the microelectronic component 50 (e.g., a level of millimeter (mm) scale; or even, micrometer (μm) scale), the soldering laser 141 emitted by the soldering laser source 140 may be irradiated to the corresponding microelectronic component 50, or adjustments may be made between a plurality of microelectronic components 50 at close distances, by using an appropriate optical guide device 170 (e.g., a galvo).

It is worth noting that as shown in FIGS. 4A and 4B, the soldering laser source 140 and the corresponding soldering laser 141 are used as an example only, and the degluing laser source 120 and the corresponding degluing laser 121 may be adopted by a similar manner, which is not be described in detail here. In addition, the direction of the laser source and/or the corresponding optical path as shown in FIGS. 4A and 4B are used as an example only and are not limited thereto in the disclosure.

FIG. 5A is a partial side view schematic of a microelectronic component transfer apparatus and the corresponding transferred object according to an embodiment of the disclosure. FIG. 5B is a partial top view schematic of a microelectronic component transfer apparatus and the corresponding transferred object according to an embodiment of the disclosure. For example, FIG. 5A may be a side view schematic corresponding to the C-C′ section line as shown in FIG. 5B.

Referring to FIGS. 5A and 5B, the backplane carrier 510 (a type of the backplane carrier 110) may include a corresponding snap, a corresponding buckle, and/or a corresponding clamp, suitable for carrying the corresponding backplane 10. The backplane 10, for example, may include an intermediate substrate in the transfer process or a display panel under manufacture, but the disclosure is not limited thereto. The side of the backplane 10 facing the substrate 30 has a metal wiring 15. The metal wiring 15 may be used to receive the microelectronic component 50. It is worth noting that as shown in FIGS. 5A and 5B, the metal wiring 15 may be illustratively depicted. In an exemplary application, the metal wiring 15 may have a corresponding layout pattern, used to provide driving signals to a plurality of microelectronic components 50 after being transferred.

FIG. 6A is a partial side view schematic of a microelectronic component transfer apparatus and the corresponding transferred object according to an embodiment of the disclosure. FIG. 6B is a partial top view schematic of a microelectronic component transfer apparatus and the corresponding transferred object according to an embodiment of the disclosure. For example, FIG. 6A may be a side view schematic corresponding to the D-D′ section line as shown in FIG. 6B.

Referring to FIGS. 6A and 6B, the backplane carrier 610 (a type of the backplane carrier 110) may include a corresponding snap, a corresponding buckle, and/or a corresponding clamp, suitable for carrying the corresponding backplane 10. In an embodiment, the backplane carrier 110 has a corresponding hollow structure 613. The hollow structure 613 may correspond to an irradiation area of the laser emitted by the laser source (e.g., the degluing laser 121 emitted by the degluing laser source 120), suitable for performing a corresponding microelectronic component transfer step. The number, size, and/or shape of the hollow structures 613 may be adjusted according to a design request, and are not limited in the disclosure. In some embodiments, the hollow structure 613 may reduce the weight of the substrate carrier 330.

### [Application of Microelectronic Component Transfer Apparatus]

The following description will provide an illustrative process of transferring the microelectronic component 50, originally disposed on the substrate 30, to the backplane 10 by using the microelectronic component transfer apparatus 100. However, it is worth noting that the application of the microelectronic component transfer apparatus 100 is not limited to the subsequent description. In addition, for clarity or brevity, some elements/components (e.g., a portion of the microelectronic component transfer apparatus 100) are omitted or symbolically depicted in the drawings.

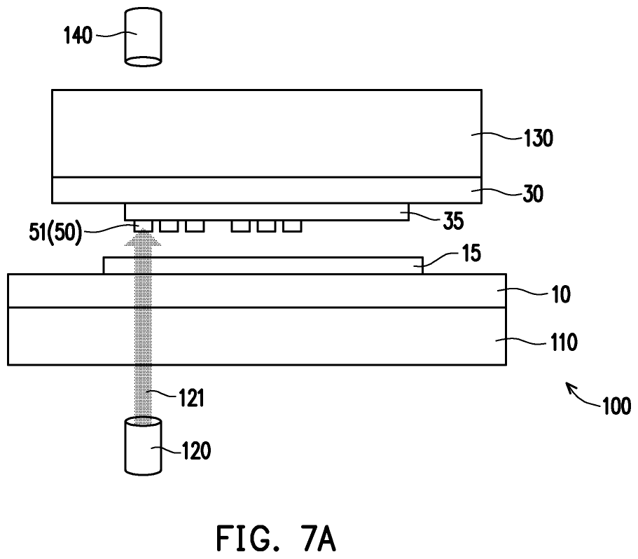

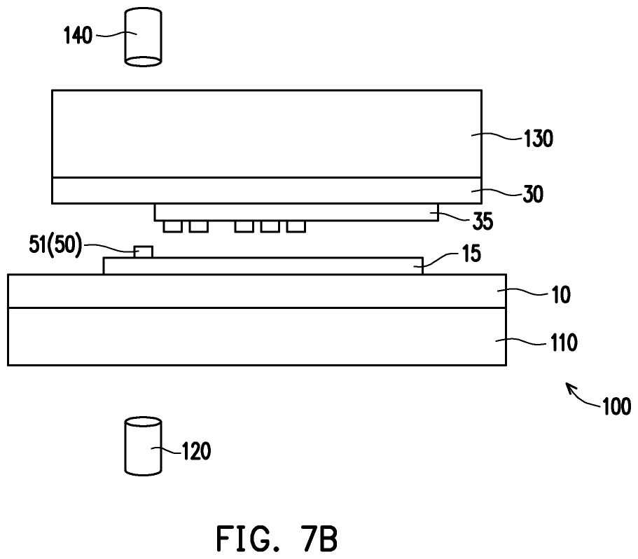

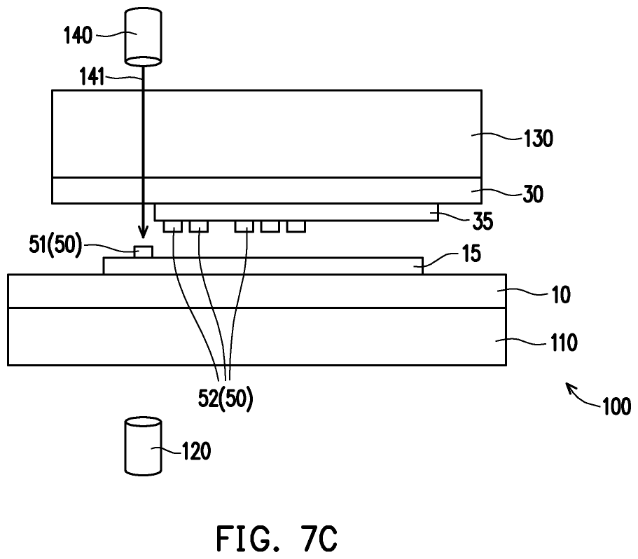

FIGS. 7A to 7C are partial side view schematics of a microelectronic component transfer process performed by a microelectronic component transfer apparatus according to an embodiment of the disclosure.

Referring to FIG. 7A, the microelectronic component 51 (one of the microelectronic components 50) temporarily fix on the substrate 30 may be disposed corresponding to the corresponding metal wiring 15 on the backplane 10 in an appropriate manner. For example, the microelectronic component 51 is temporarily fixed to the surface of the substrate 30 facing the backplane 10 by an adhesive layer 35.

Referring to FIG. 7A continuously, the degluing laser source 120 emits the degluing laser 121 from one side of the backplane 10 towards the substrate carrier 130. After the degluing laser 121 passes through the backplane 10, it irradiates a portion of the adhesive layer 35 on the substrate 30. The degluing laser 121 may be focused on a portion of the adhesive layer 35 on the substrate 30 in an appropriate manner or by an appropriate device. The irradiated portion of the adhesive layer 35 corresponds to the microelectronic component 51.

Referring to FIGS. 7A to 7B, the adhesive force of the portion of the adhesive layer 35 irradiated by the degluing laser 121 is reduced or decomposed, thereby allowing the microelectronic component 51 and the substrate 30 to be separated from each other. Moreover, for example, the separated microelectronic component 51 may be fall onto the corresponding metal wiring 15 on the backplane 10 by gravity.

Referring to FIGS. 7B to 7C, after the microelectronic component 51 falls onto the corresponding metal wiring 15 on the backplane 10, the soldering laser 141 emitted by the soldering laser source 140 from one side of the substrate carrier 130 towards the backplane carrier 110 passes through the substrate 30 and irradiates the microelectronic component 51 or the conductive connector 60 disposed between the microelectronic component 51 and the metal wiring 15. The soldering laser 141 may be focused on the microelectronic component 51 or the conductive connector 60 on the backplane 10 in an appropriate manner or by an appropriate device. In this way, the microelectronic component 51 may be fixed on the backplane 10 by soldering, and may be electrically connected to the corresponding metal wiring 15. In some embodiments, the soldering laser 141 only focuses on the conductive connector 60 and the metal wiring 15, which may reduce the possibility of the microelectronic component 51 being damaged by the thermal energy or high temperature of the soldering laser 141.

Furthermore, the soldering laser 141 emitted by the soldering laser source 140 is essentially irradiated directly onto the corresponding conductive connector 60 and/or metal wiring 15 without passing through the backplane 10. In this way, the heated area and/or temperature of the metal wiring 15 may be reduced, thereby the impact of excess waste heat on process quality and/or yield may be reduced.

In an embodiment, the degluing laser source 120 and the soldering laser source 140 are configured in a relative manner. In an embodiment, for the transferred microelectronic component 51, the soldering laser 141 and the degluing laser 121 have different irradiation directions but are basically coaxial.

Other microelectronic components 52 (those different from microelectronic component 51 among the microelectronic components 50, not be labelled individually) temporarily fixed on the substrate 30 may also be transferred in the same or similar manner as aforementioned, which is not be described in detail here. It is worth noting that the disclosure does not limit the order of transfer of the microelectronic components 50 temporarily fixed on the substrate 30.

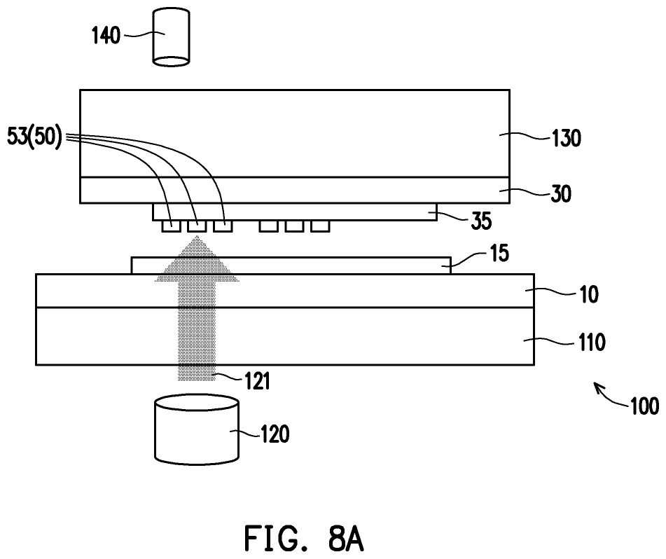

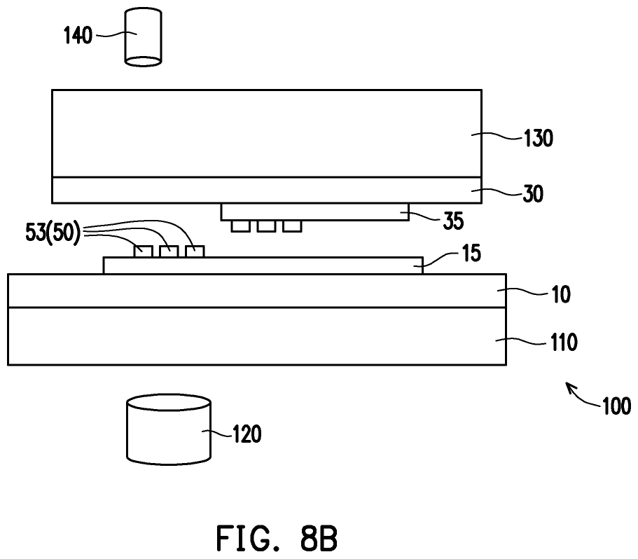

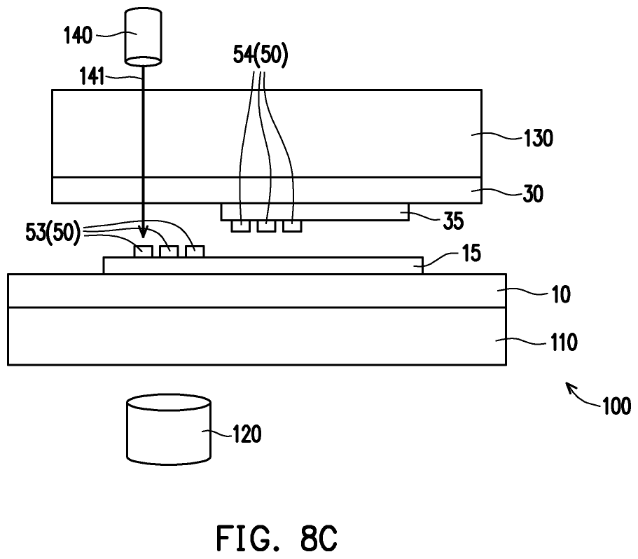

FIGS. 8A to 8C are partial side schematic views of a microelectronic component transfer process performed by a microelectronic component transfer apparatus according to an embodiment of the disclosure.

Referring to FIG. 8A, a plurality of microelectronic components 53 (a portion of the microelectronic components 50) temporarily fix on the substrate 30 may be disposed respectively corresponding to the corresponding metal wiring 15 on the backplane 10 in an appropriate manner.

Referring to FIG. 8A continuously, the degluing laser source 120 emits the degluing laser 121 towards the direction of the substrate carrier 130. The degluing laser 121 may be focused on a portion of the adhesive layer 35 on the substrate 30 by an appropriate manner or by an appropriate device. The irradiated portion of the adhesive layer 35 corresponds to the plurality of microelectronic components 53. That is, the light spot formed after the degluing laser 121 is focused may correspond to the area of the plurality of microelectronic components 53.

Referring to FIGS. 8A to 8B, the portion of the adhesive layer 35 irradiated by the degluing laser 121 reduces adhesion or decomposes, therefore allowing the plurality of microelectronic components 53 to be separated from the substrate 30. Moreover, for example, the separated microelectronic components 53 may fall onto the corresponding metal wiring 15 on the backplane 10 by gravity.

Referring to FIGS. 8B to 8C, after the plurality of microelectronic components 53 fall onto the corresponding metal wiring 15 on the backplane 10, the soldering laser source 140 emits the soldering laser 141 towards the direction of the backplane carrier 110. The soldering laser 141 may be focused on the microelectronic components 53 on the backplane 10 by an appropriate manner or by an appropriate device. In this way, the microelectronic components 53 may be fixed on the backplane 10 by soldering, and may be electrically connected to the corresponding metal wiring 15. In some embodiments, the light spot formed after the degluing laser 121 is focused corresponds to the area of the plurality of microelectronic components 53, and the light spot formed after the soldering laser 141 is focused corresponds to the area of a single microelectronic component 53. That is, the light spot of the focused degluing laser 121 is larger than the light spot of the focused soldering laser 141.

In an embodiment, different microelectronic components 53 may be soldered in sequence by an appropriate manner. For example, the light spot formed after the degluing laser 121 is focused may correspond to the area of a single microelectronic component 53, and each microelectronic component 53 may be soldered sequentially or not simultaneously.

Other microelectronic components 54 (those different from the microelectronic components 53 among the microelectronic components 50, not be labelled individually) temporarily fixed on the substrate 30 may also be transferred in the same or similar manner as aforementioned, which is not be described in detail here.

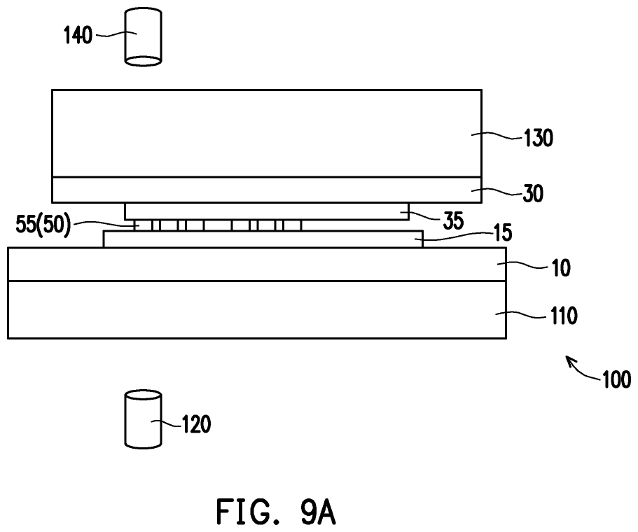

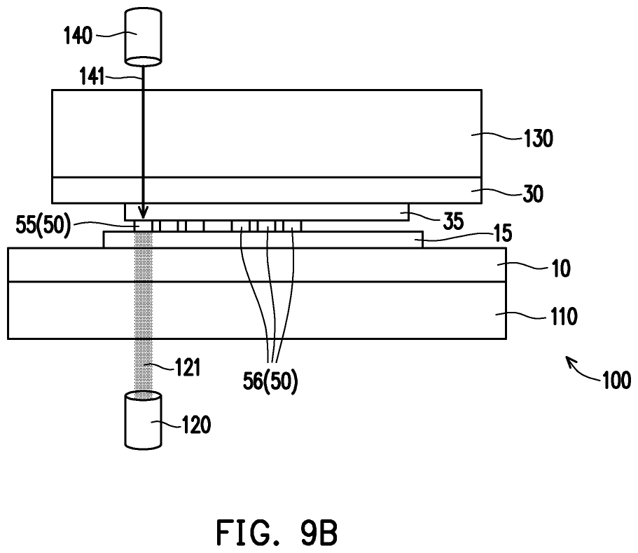

FIGS. 9A to 9B are partial side schematic views of a microelectronic component transfer process performed by a microelectronic component transfer apparatus according to an embodiment of the disclosure.

Referring to FIG. 9A, an appropriate manner may be performed for configuring the substrate carrier 130 and the backplane carrier 110 closer to each other, and for configuring the microelectronic components 50 temporarily fixed on the substrate 30 closer to or even in contact with the corresponding metal wiring 15 on the backplane 10. It is worth noting that at this time, the microelectronic components 50 to be transferred are still temporarily fixed on the substrate 30.

Referring to FIGS. 9A to 9B, by the same or similar manner as aforementioned, the degluing laser 121 is focused and irradiated on a portion of the adhesive layer 35 on the substrate 30, and the soldering laser 141 is focused and irradiated on the microelectronic component 55 (one of the microelectronic components 50) on the backplane 10. In this way, the corresponding microelectronic component 55 may be separated from the substrate 30, and the microelectronic component 55 may be fixed on the backplane 10. It is worth noting that the disclosure does not limit the enabling timing of the degluing laser 121 and the soldering laser 141. For example, the timing of emitting the degluing laser 121 and emitting the soldering laser 141 may overlap, which may improve the efficiency or throughput of the microelectronic component transfer apparatus 100.

Other microelectronic components 56 (those different from the microelectronic components 55 among the microelectronic components 50, not be labelled individually) temporarily fixed on the substrate 30 may also be transferred in the same or similar manner as aforementioned, which is not be described in detail here.

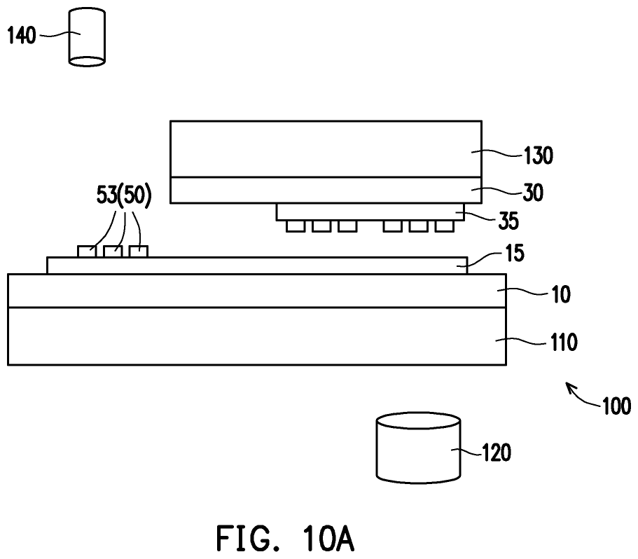

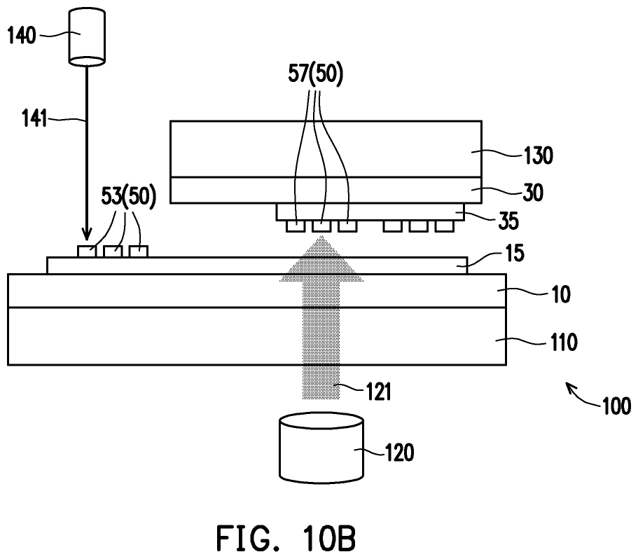

FIGS. 10A to 10B are partial side schematic views of a microelectronic component transfer process performed by a microelectronic component transfer apparatus according to an embodiment of the disclosure. For example, FIGS. 10A to 10B may be the steps following FIG. 8B.

Referring to FIGS. 8B and 10A, after the separated microelectronic components 53 fall onto the corresponding metal wiring 15 on the backplane 10 (as shown in FIG. 8B), an appropriate manner may be performed for configuring the degluing laser source 120 and the substrate carrier 130 not overlap with other areas of the plurality of microelectronic components 53 (as shown in FIG. 10A). For example, the degluing laser source 120 and the substrate carrier 130 may be moved in a plane parallel to the substrate 30 and the backplane 10; and/or, the soldering laser source 140 and the backplane carrier 110 may be moved in a plane parallel to the substrate 30 and the backplane 10.

Referring to FIGS. 10A and 10B, after configuring the degluing laser source 120 and the substrate carrier 130 not overlap with the plurality of microelectronic components 53 (as shown in FIG. 10A), the soldering laser source 140 may emit the soldering laser 141 towards the direction of the backplane carrier 110, thereby the microelectronic components 53 are fixed on the backplane 10 by soldering, and may electrically connect to the corresponding metal wiring 15.

Referring to FIGS. 10A and 10B, after configuring the degluing laser source 120 and the substrate carrier 130 not overlap with the plurality of microelectronic components 53 (as shown in FIG. 10A), the degluing laser source 120 may emit the degluing laser 121 towards the direction of the substrate carrier 130 in the same or similar manner as aforementioned (as shown in FIGS. 8A to 8B), thereby the plurality of microelectronic components 57 (another portion of the microelectronic components 50 different from the microelectronic components 53) may be separated from the substrate 30.

It is worth noting that in FIG. 10B, the enabling timing of the degluing laser 121 and the soldering laser 141 is not limited in the disclosure. For example, the timing of emitting the degluing laser 121 and emitting the soldering laser 141 may overlap, which may improve the efficiency or throughput of the microelectronic component transfer apparatus 100.

In summary, when the microelectronic component transfer process is performed by the microelectronic component transfer apparatus of the disclosure, due to the corresponding configuration of the degluing laser source and the soldering laser source, the transfer process may have better process quality and/or yield.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A microelectronic component transfer apparatus, comprising:
a backplane carrier, for carrying a backplane;
a substrate carrier, for carrying a substrate, wherein the substrate carrier is configured opposite to the backplane carrier;
a degluing laser source, configured on a side of the backplane carrier far away from the substrate carrier, and for emitting a degluing laser towards a direction of the substrate carrier; and
a soldering laser source, configured on a side of the substrate carrier far away from the backplane carrier, and for emitting a soldering laser towards a direction of the backplane carrier, thereby transferring a microelectronic component disposed on the substrate to the backplane.

2. The microelectronic component transfer apparatus according to claim 1, wherein a wavelength of the degluing laser source is less than a wavelength of the soldering laser source, and a pulse width of the degluing laser source is greater than a pulse width of the soldering laser source.

3. The microelectronic component transfer apparatus according to claim 1, wherein an adhesive layer is disposed on a side of the substrate facing the backplane, thereby the microelectronic component is temporarily fixed.

4. The microelectronic component transfer apparatus according to claim 3, wherein the degluing laser emitted by the degluing laser source towards the direction of the substrate carrier is focused on the adhesive layer disposed on the substrate, thereby the microelectronic component is separated from the substrate.

5. The microelectronic component transfer apparatus according to claim 1, wherein a side of the backplane facing the substrate comprises a metal wiring for receiving the microelectronic component.

6. The microelectronic component transfer apparatus according to claim 5, wherein the soldering laser emitted by the soldering laser source towards the direction of the backplane carrier is focused on the microelectronic component, thereby the microelectronic component is soldered to the metal wiring.

7. The microelectronic component transfer apparatus according to claim 5, wherein the microelectronic component comprises a conductive connector, the conductive connector is disposed on a side of the microelectronic component facing the backplane, the soldering laser emitted by the soldering laser source towards the direction of the backplane carrier is focused on the conductive connector, thereby the microelectronic component is soldered to the metal wiring.

8. The microelectronic component transfer apparatus according to claim 1, wherein the backplane carrier has a hollow structure corresponding to an irradiation area of the degluing laser.

9. The microelectronic component transfer apparatus according to claim 1, wherein the substrate carrier has a hollow structure corresponding to an irradiation area of the soldering laser.

10. The microelectronic component transfer apparatus according to claim 1, wherein a light spot formed after the degluing laser is focused is larger than a light spot formed after the soldering laser is focused.

11. The microelectronic component transfer apparatus according to claim 1, wherein the backplane carrier and the substrate carrier are respectively driven by two-dimensional translation equipments that are parallel to each other, thereby the relative positions of the backplane carrier and the substrate carrier with the degluing laser source and the soldering laser source change are changed.

12. The microelectronic component transfer apparatus according to claim 1, wherein the degluing laser source and the soldering laser source are respectively driven by two-dimensional translation equipments, for moving on a plane parallel to the substrate and the backplane.

13. The microelectronic component transfer apparatus according to claim 1, wherein the degluing laser source and the soldering laser source change the emission directions of the degluing laser and the soldering laser respectively through corresponding optical guide devices.
